(19) United States
(12) Patent Application Publication
(10) Pub. No.: US 2016/0042872 A1
(43) Pub. Date: Feb. 11, 2016

(54) COMPOSITE ELECTRONIC COMPONENT, BOARD HAVING THE SAME, AND PACKAGING UNIT THEREOF

(71) Applicant: SAMSUNG ELECTRO-MECHANICS CO., LTD., Suwon-Si (KR)

(72) Inventors: Yu Jin CHOI, Suwon-Si (KR); Soo Hwan SON, Suwon-Si (KR)

(21) Appl. No.: 14/638,816

(22) Filed: Mar. 4, 2015

(30) Foreign Application Priority Data
Aug. 11, 2014 (KR) 10-2014-0103970

(51) Int. Cl. H01G 4/40; H01G 4/30; H01F 27/29; H05K 1/11; H01F 27/28; H01G 4/12; H05K 1/18

(52) U.S. Cl. CPC H01G 4/40; H01G 4/12; H01G 4/306; H05K 1/181; H05K 1/111; H01F 27/2804; H01F 27/292; H01F 2027/2809

(57) ABSTRACT

A composite electronic component includes: a composite body having a capacitor and an inductor coupled to each other, the capacitor including a ceramic body in which a plurality of dielectric layers and first and second internal electrodes disposed to oppose each other with each of the dielectric layers interposed therebetween are stacked, and the inductor including a magnetic body including a coil part; an input terminal disposed on a first side surface of the composite body; an output terminal including a first output terminal disposed on a second side surface of the composite body and a second output terminal disposed on the second side surface of the composite body; and a ground terminal disposed on the first side surface of the composite body.

### CROSS-REFERENCE TO RELATED APPLICATION

This application claims the priority and benefit of Korean Patent Application No. 10-2014-0103970 filed on Aug. 11, 2014, with the Korean Intellectual Property Office, the disclosure of which is incorporated herein by reference.

### BACKGROUND

The present inventive concept relates to a composite electronic component including a plurality of passive elements, a board having the same, and a packaging unit thereof.

In accordance with recent consumer demand for thinness and lightness in electronic apparatuses and improvements in the performance thereof, electronic apparatuses have been required to have a significantly decreased size and increased functionality.

Such electronic apparatuses commonly include a power semiconductor based power management integrated circuit (PMIC), serving to efficiently control and manage limited battery resources in order to satisfy requirements of providing various services.

However, as ever greater degrees of functionality have been provided in electronic apparatuses, amounts of direct current (DC)-to-DC converters included in PMICs have increased. In addition, the amounts of passive components that need to be included in power input terminals and power output terminals of the PMIC have also been increased.

In this case, since an area of such an electronic apparatus in which components are disposed is invariably increased, limitations may be placed on the miniaturization of electronic apparatuses.

In addition, a large amount of noise may be generated due to the PMIC and wiring patterns of peripheral circuits of the PMIC.

In order to solve the above-mentioned issues, research into a composite electronic component in which an inductor and a capacitor are coupled to each other in a vertical manner has been conducted, such that effects such as a decrease in an area of the electronic apparatus in which the components are disposed and suppression of noise generation have been obtained.

However, in the case in which the inductor and the capacitor are vertically disposed, as described above, an amount of magnetic flux generated in the inductor has an influence on internal electrodes of the capacitor to generate parasitic capacitance, and thereby a self resonant frequency (SRF) may move toward a low frequency band.

Meanwhile, in accordance with the miniaturization of such composite electronic components, a thickness of an internal magnetic layer blocking a magnetic field of the inductor may also be reduced, such that a quality (Q) factor may be deteriorated.

Meanwhile, in a case of manufacturing a composite electronic component in which a multilayer ceramic capacitor and the inductor are coupled to each other, such a composite electronic component has been manufactured only focusing on adhesion between the multilayer ceramic capacitor and the inductor, passive components.

In this case, no issues may arise in terms of product characteristics subsequently to the composite electronic component being manufactured. However, a spot of an epoxy resin may appear on an outer casing of a product, and a bonding portion between the multilayer ceramic capacitor and the inductor may be twisted, such that a step difference may be generated in a composite body.

In the case in which the step difference is generated in the composite body as described above, pick-up defects may commonly occur at the time of mounting the composite electronic component on a board, and the aesthetic appearance of a product may be negatively affected.

### RELATED ART DOCUMENT

Korean Patent Laid-Open Publication No. 2003-0014586

### SUMMARY

An aspect of the present inventive concept may provide a composite electronic component able to be mounted in a relatively decreased area of a driving power supplying system, a board having the same, and a packaging unit thereof.

An aspect of the present inventive concept may also provide a composite electronic component capable of suppressing noise generation in a driving power supplying system, a board having the same, and a packaging unit thereof.

An aspect of the present inventive concept may also provide a composite electronic component capable of reducing an influence of a step difference that may be generated on a coupling surface between a plurality of components and preventing pick-up defects, a board having the same, and a packaging unit thereof.

According to an aspect of the present inventive concept, a composite electronic component may include: a composite body having a capacitor and an inductor coupled to each other, the capacitor including a ceramic body in which a plurality of dielectric layers and first and second internal electrodes disposed to oppose each other with each of the dielectric layers interposed therebetween are stacked, and the inductor including a magnetic body including a coil part; an input terminal disposed on a first side surface of the composite body in a length direction of the composite body and connected to the coil part of the inductor; an output terminal including a first output terminal disposed on a second side surface of the composite body in the length direction of the composite body and connected to the coil part of the inductor and a second output terminal disposed on the second side surface of the composite body in the length direction of the composite body and connected to the first internal electrode of the capacitor; and a ground terminal disposed on the first side surface of the composite body in the length direction of the composite body and connected to the second internal electrode of the capacitor, wherein the composite body has a pigment layer disposed on the other surface of the composite body opposing a mounting surface of the composite body.

The pigment layer may contain one or more of an epoxy resin, an organic pigment, and an inorganic pigment and may be disposed on the entirety of the other surface of the composite body opposing the mounting surface of the composite body.

According to another aspect of the present inventive concept, a composite electronic component may include: an input terminal receiving power converted by a power managing part to be supplied thereto; a power stabilizing part stabilizing the power and including a composite body having a capacitor and an inductor coupled to each other, the capacitor including a ceramic body in which a plurality of dielectric layers and first and second internal electrodes disposed to oppose each other with each of the dielectric layers interposed therebetween are stacked and being coupled to a side surface of the inductor and the inductor including a magnetic body including a coil part; an output terminal supplying the stabilized power; and a ground terminal for a connection to a ground, wherein the composite body has a pigment layer disposed on the other surface of the composite body opposing a mounting surface of the composite body.

According to still another aspect of the present inventive concept, a board having a composite electronic component may include: a printed circuit board (PCB) on which three or more electrode pads are disposed; the composite electronic component as described above mounted on the PCB; and solders respectively connecting the electrode pads and the composite electronic component to each other.

According to yet another aspect of the present inventive concept, a packaging unit of a composite electronic component may include: the composite electronic component as described above; and a packing sheet having an accommodating part formed therein, the accommodating part accommodating the composite electronic component therein, wherein the pigment layer is disposed to face upward, based on a bottom surface of the accommodating part.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view schematically illustrating a composite electronic component according to an exemplary embodiment of the present inventive concept;

FIG. 2 is a schematic perspective view illustrating an inner portion of the composite electronic component of FIG. 1 according to a first exemplary embodiment;

FIG. 3 is a schematic perspective view illustrating an inner portion of the composite electronic component of FIG. 1 according to a second exemplary embodiment;

FIG. 4 is a schematic perspective view illustrating an inner portion of a composite electronic component of FIG. 1 according to a third exemplary embodiment;

FIG. 5 is a plan view illustrating internal electrodes that may be used in a multilayer ceramic capacitor in the composite electronic component illustrated in FIG. 1;

FIG. 6 is a view illustrating a driving power supplying system supplying driving power to a predetermined terminal requiring the driving power through a battery and a power managing part;

FIG. 7 is a view illustrating a pattern in which the driving power supplying system is disposed;

FIG. 8 is a circuit diagram of a composite electronic component according to an exemplary embodiment of the present inventive concept;

FIG. 9 is a view illustrating a pattern in which a driving power supplying system using a composite electronic component according to an exemplary embodiment of the present inventive concept is disposed;

FIG. 10 is a perspective view illustrating a form in which the composite electronic component of FIG. 1 is mounted on a printed circuit board (PCB);

FIG. 11 is a schematic perspective view illustrating a form in which the composite electronic components of FIG. 1 are mounted in a packaging unit; and

FIG. 12 is a schematic cross-sectional view illustrating the packaging unit of FIG. 11 wound in a coil form.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

Composite Electronic Component

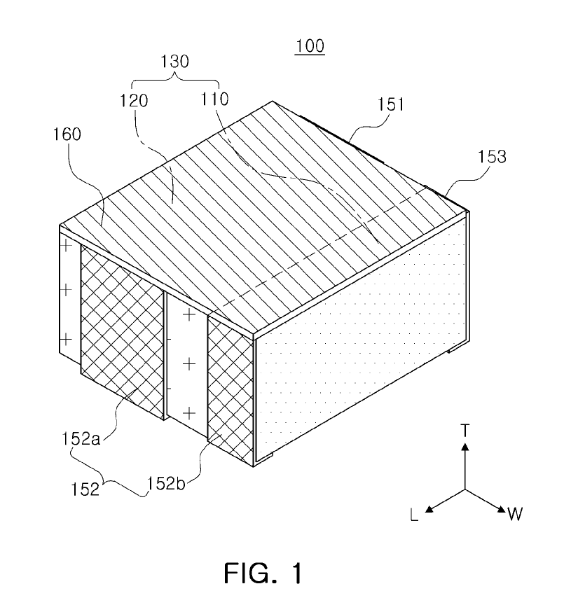

FIG. 1 is a perspective view schematically illustrating a composite electronic component according to an exemplary embodiment of the present inventive concept.

Referring to FIG. 1, in a composite electronic component according to an exemplary embodiment of the present inventive concept, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ refers to a direction in which dielectric layers of a capacitor are stacked, that is, a ‘stacked direction’.

Meanwhile, the length direction, the width direction, and the thickness direction of the composite electronic component are the same as those of a capacitor and an inductor as will be described below.

In addition, in an exemplary embodiment of the present inventive concept, the composite electronic component may have upper and lower surfaces opposing each other, and first and second side surfaces connecting the upper and lower surfaces to each other and disposed in the length direction the composite electronic component and first and second side surfaces connecting the upper and lower surfaces to each other and disposed in the width direction of the composite electronic component. The shape of the composite electronic component is not particularly limited, but may be a hexahedral shape as illustrated in FIG. 1.

In addition, the first and second side surfaces of the composite electronic component in the length direction of the composite electronic component and the first and second side surfaces thereof in the width direction of the composite electronic component may be the same as first and second side surfaces of a capacitor in a length direction of the capacitor and first and second side surfaces thereof in a width direction of the capacitor, respectively, and may be the same as first and second side surfaces of an inductor in a length direction of the inductor and first and second side surfaces thereof in a width direction of the inductor, respectively, as will be described below.

Meanwhile, the composite electronic component may have a form in which the capacitor and the inductor are coupled to each other. In a case in which the capacitor is coupled to a side surface of the inductor, an upper surface of the composite electronic component may refer to an upper surface of each of the inductor and the capacitor and a lower surface of the composite electronic component may refer to a lower surface of each of the inductor and the capacitor.

In addition, the upper and lower surfaces of the composite electronic component may correspond to surfaces of the composite electronic component opposing each other in the thickness direction of the composite electronic component.

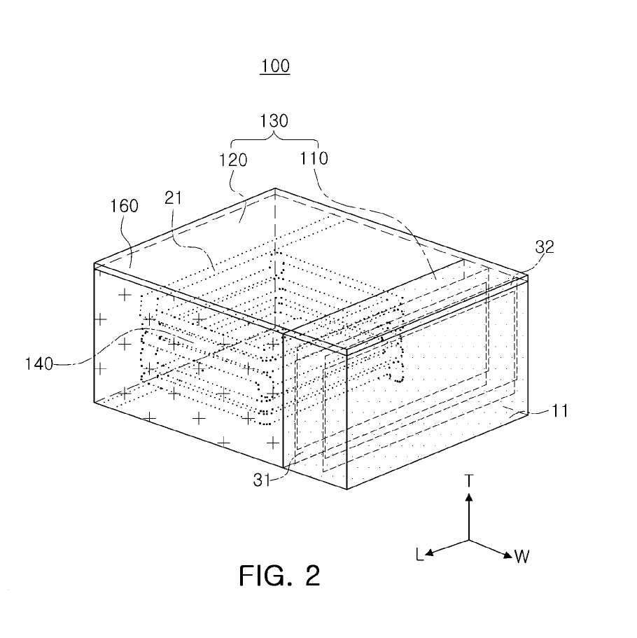

FIG. 2 is a schematic perspective view illustrating an inner portion of the composite electronic component of FIG. 1 according to a first exemplary embodiment.

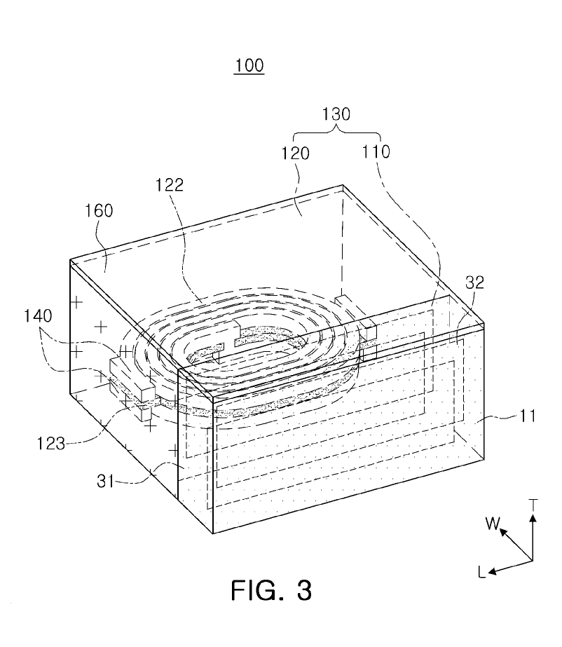

FIG. 3 is a schematic perspective view illustrating an inner portion of the composite electronic component of FIG. 1 according to a second exemplary embodiment.

Referring to FIGS. 1 through 3, a composite electronic component 100 according to an exemplary embodiment of the present inventive concept may include a composite body 130 having a capacitor 110 and an inductor 120 coupled to each other, wherein the capacitor 110 includes a ceramic body in which a plurality of dielectric layers 11 and first and second internal electrodes 31 and 32 disposed to oppose each other with each of the dielectric layers 11 interposed therebetween are stacked, and the inductor 120 includes a magnetic body including a coil part 140.

In the present exemplary embodiment, the composite body 130 may have upper and lower surfaces opposing each other, and first and second side surfaces in the length direction of the composite body 130 and first and second side surfaces in the width direction of the composite body 130 that connect the upper and lower surfaces to each other.

The shape of the composite body 130 is not particularly limited, but may be a hexahedral shape as illustrated in FIGS. 1 through 3.

The composite body 130 may be formed by coupling the capacitor 110 and the inductor 120 to each other. However, the manner of forming the composite body 130 is not particularly limited.

For example, the composite body 130 may be formed by coupling the capacitor 110 and the inductor 120 that are separately manufactured, to each other by a conductive adhesive, a resin, or the like, but the manner of coupling the composite body 130 is not limited thereto.

In particular, the adhesive or the resin used to couple the capacitor 110 and the inductor 120 to each other may be, for example, an epoxy resin, but is not limited thereto.

The manner of coupling the capacitor 110 and the inductor 120 to each other using the conductive adhesive, the resin, or the like, is not particularly limited. For example, the capacitor 110 and the inductor 120 may be coupled to each other by applying the conductive adhesive, the resin, or the like, on a coupling surface of the capacitor 110 or the inductor 120 and by heating and hardening the conductive adhesive, the resin, or the like.

Meanwhile, according to the exemplary embodiment of the present inventive concept, the capacitor 110 may be coupled to a side surface of the inductor 120, but the disposition of the capacitor 110 and the inductor 120 is not limited thereto. That is, the capacitor 110 and the inductor 120 may be disposed in various manners.

Hereinafter, the capacitor 110 and the inductor 120 configuring the composite body 130 will be described in detail.

According to the exemplary embodiment of the present inventive concept, the magnetic body configuring the inductor 120 may include the coil part 140.

The inductor 120 is not particularly limited, but may be, for example, a multilayer type inductor, a thin film type inductor, or a winding type inductor.

The multilayer type inductor may be manufactured by printing thick films of electrodes on thin ferrite or glass ceramic sheets, and through via-holes, stacking several layers of printed coil patterns and connecting internal conductive wires to each other.

The thin film type inductor may be manufactured by forming a coil, a conductive wire, on a ceramic substrate by thin film sputtering or plating and filling with a ferrite material.

The winding type inductor may be manufactured by winding a wire, a conductive wire, around a core.

Referring to FIG. 2, in a composite electronic component according to a first exemplary embodiment of the present inventive concept, the inductor 120 may be the multilayer type inductor.

In detail, the magnetic body may have a form in which a plurality of magnetic layers 21 having conductive patterns respectively formed thereon are stacked, wherein the conductive patterns 41 may form the coil part 140.

Referring to FIG. 3, in a composite electronic component according to a second exemplary embodiment of the present inventive concept, the inductor 120 may be the thin film type inductor.

In detail, the inductor 120 may have a thin film form in which the magnetic body includes an insulating substrate 123 and a coil formed on at least one surface of the insulating substrate 123.

The magnetic body may be formed by filling upper and lower portions of the insulating substrate 123 having the coil formed on at least one surface of the insulating substrate 123 with magnetic materials 122.

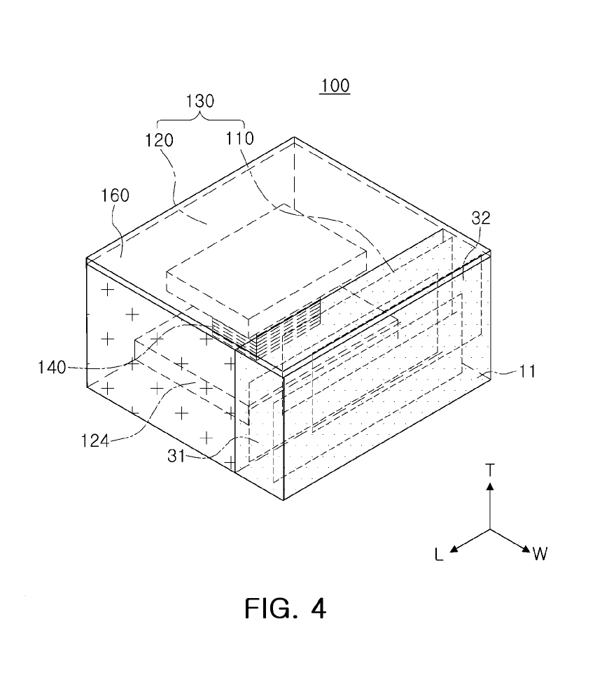

FIG. 4 is a schematic perspective view illustrating an inner portion of the composite electronic component of FIG. 1 according to a third exemplary embodiment.

Referring to FIG. 4, in a composite electronic component according to a third exemplary embodiment of the present inventive concept, the inductor 120 may be the winding type inductor.

In detail, in the inductor 120, the magnetic body may include a core 124 and a winding coil wound around the core 124.

Referring to FIGS. 2 through 4, the first and second internal electrodes 31 and 32 of the capacitor 110 may be stacked to be perpendicular to a mounting surface of the composite body, but the stacking manner of the first and second internal electrodes 31 and 32 is not limited thereto. That is, the first and second internal electrodes 31 and 32 may also be stacked to be horizontal to the mounting surface of the composite body.

The magnetic layer 21 and the magnetic material 122 may be formed of a Ni—Cu—Zn based material, a Ni—Cu—Zn—Mg based material, or a Mn—Zn based material, but the material forming the magnetic layer 21 and the magnetic material 122 is not limited thereto.

According to an exemplary embodiment of the present inventive concept, the inductor 120 may be a power inductor that may be applied to a large amount of currents.

The power inductor may be a high efficiency inductor in which an inductance change is smaller than that in a conventional inductor when a direct current (DC) current is applied thereto. That is, it may be considered that the power inductor includes DC bias characteristics, for example, a change in inductance of the power inductor when the DC current is applied thereto in response to the DC current being applied thereto, in addition to a function of the conventional inductor.

That is, the composite electronic component according to the exemplary embodiment of the present inventive concept, which is used in a power management integrated circuit (PMIC), may include the power inductor, that is, a high efficiency inductor in which an inductance change is relatively small when the DC current is applied thereto, rather than a conventional inductor.

Meanwhile, the ceramic body configuring the capacitor 110 may be formed by stacking the plurality of dielectric layers 11, and a plurality of internal electrodes 31 and 32, for example, first and second internal electrodes 31 and 32, may be disposed in the ceramic body to be spaced apart from each other with each of the dielectric layers interposed therebetween.

The dielectric layer 11 may be formed by sintering a ceramic green sheet containing ceramic powder particles, an organic solvent, and an organic binder. The ceramic powder particles, a high-k material, may be a barium titanate (BaTiO₃) based material, a strontium titanate (SrTiO₃) based material, or the like, but are not limited thereto.

Meanwhile, according to the exemplary embodiment of the present inventive concept, the first and second internal electrodes 31 and 32 may be exposed to the second and first side surfaces of the composite body 130 in the length direction of the composite body 130, respectively, but the exposure of the first and second internal electrodes 31 and 32 is not necessarily limited thereto.

According to the exemplary embodiment of the present inventive concept, the first and second internal electrodes 31 and 32 may be formed of a conductive paste containing a conductive metal.

The conductive metal may be nickel (Ni), copper (Cu), palladium (Pd), or an alloy thereof, but is not limited thereto.

The first and second internal electrodes 31 and 32 may be printed on the ceramic green sheets forming the dielectric layer 11, using conductive pastes by a printing process such as a screen printing process or a gravure printing process.

The ceramic green sheets on which the internal electrodes are printed may be alternatingly stacked and sintered to form the ceramic body.

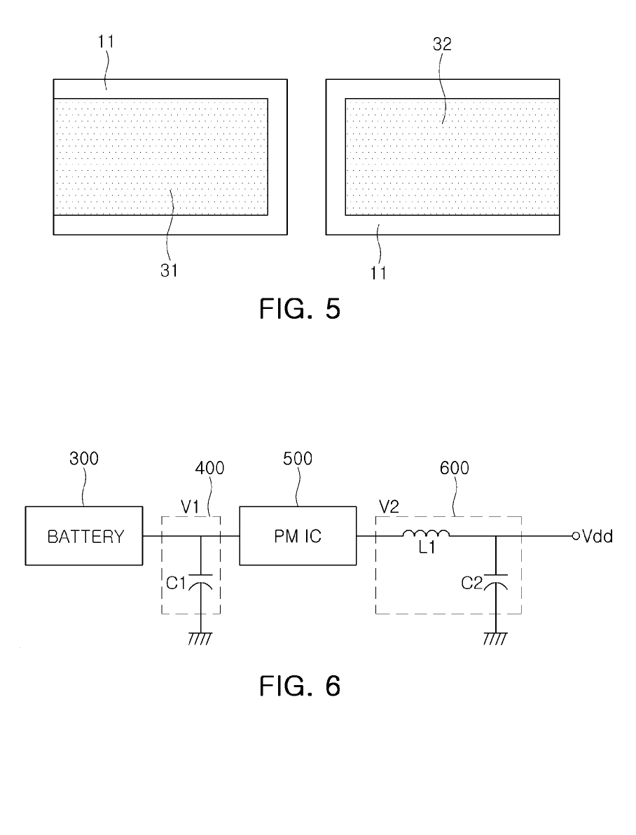

FIG. 5 is a plan view illustrating internal electrodes that may be used in a multilayer ceramic capacitor in the composite electronic component illustrated in FIG. 1.

Although pattern shapes of the first and second internal electrodes 31 and 32 are illustrated in FIG. 5, they are not limited thereto, but may be modified in various manners.

The capacitor may serve to control a voltage supplied from a PMIC.

The composite electronic component 100 according to the exemplary embodiment of the present inventive concept may include an input terminal 151 disposed on the first side surface of the composite body 130 in the length direction of the composite body 130 and connected to the coil part 140 of the inductor 120, an output terminal 152 including a first output terminal 152a disposed on the second side surface of the composite body 130 in the length direction of the composite body 130 and connected to the coil part 140 of the inductor 120 and a second output terminal 152b disposed on the second side surface of the composite body 130 in the length direction of the composite body 130 and connected to the first internal electrode 31 of the capacitor 110, and a ground terminal 153 disposed on the first side surface of the composite body 130 in the length direction of the composite body 130 and connected to the second internal electrode 32 of the capacitor 110.

The input terminal 151 and the first output terminal 152a may be connected to the coil part 140 of the inductor 120 to serve as the inductor in the composite electronic component.

In addition, the second output terminal 152b may be connected to the first internal electrodes 31 of the capacitor 110 and the second internal electrodes 32 of the capacitor 110 may be connected to the ground terminal 153, such that the second output terminal 152b and the ground terminal 153 may serve as the capacitor in the composite electronic component.

The input terminal 151, the output terminal 152, and the ground terminal 153 may be formed of a conductive paste containing a conductive metal.

The conductive metal may be Ni, Cu, tin (Sn), or an alloy thereof, but is not limited thereto.

The conductive paste may further contain an insulating material. The insulating material may be, for example, glass, but is not limited thereto.

A manner of forming the input terminal 151, the output terminal 152, and the ground terminal 153 is not particularly limited. That is, the input terminal 151, the output terminal 152, and the ground terminal 153 may be formed by dipping the ceramic body or may be formed by another process such as a printing process, a plating process, or the like.

According to the exemplary embodiment of the present inventive concept, a pigment layer 160 may be disposed on the other surface of the composite body 130 opposing the mounting surface of the composite body 130.

Generally, in the case of manufacturing the composite electronic component in which the multilayer ceramic capacitor and the inductor are coupled to each other, the composite electronic component has been manufactured only focusing on adhesion between the multilayer ceramic capacitor and the inductor, which are passive components.

In this case, no issues may arise in terms of product characteristics subsequently to the composite electronic component being manufactured. However, a spot of an epoxy resin may appear on an outer casing of a product, and a bonding portion between the multilayer ceramic capacitor and the inductor may be twisted, such that a step difference may be generated in a composite body.

In the case in which the step difference is generated in the composite body as described above, pick-up defects may commonly occur at the time of mounting the composite electronic component on a board, and the aesthetic appearance of a product may be negatively affected.

According to the exemplary embodiment of the present inventive concept, the pigment layer 160 may be disposed on the other surface of the composite body 130 opposing the mounting surface of the composite body 130 to prevent defects in an aesthetic appearance due to a flow spot of an epoxy resin, or the like, whereby a product value may be enhanced through upgrading quality of the product.

In addition, in the case in which the step difference is present on a surface of the product, the pigment layer 160 may be disposed on the other surface of the composite body 130 opposing the mounting surface of the composite body 130 to reduce the step difference, thereby preventing pick-up defects at the time of mounting the composite electronic component 100 according to the exemplary embodiment of the present inventive concept on the board.

In addition, a pigment such as epoxy, or the like, may be injected into a bonding interface between the multilayer ceramic capacitor 110 and the inductor 120 in a process in which the pigment layer 160 is disposed on the other surface of the composite body 130 opposing the mounting surface of the composite body 130, and thereby bonding strength between components coupled to each other may be improved.

The pigment layer 160 may contain one or more of an epoxy resin, an organic pigment, and an inorganic pigment, and is not particularly limited as long as it contains a general pigment.

One or more of the epoxy resin, the organic pigment, and the inorganic pigment contained in the pigment layer 160 may have a black color as a desirable color by way of example.

The organic pigment is not particularly limited, but may be, for example, an azo pigment, a phthalocyanine based pigment, a dye lake pigment, a condensed polycyclic pigment, and the like.

The inorganic pigment is not particularly limited, but may be, for example, a metal oxide, a metal hydroxide, or a metal sulfide, and may have a form such as a chromate, a silicate, a sulfate, a carbonate, and the like.

The pigment layer 160 may be disposed on the entirety of the other surface of the composite body 130 opposing the mounting surface of the composite body 130.

The pigment layer 160 may be disposed on the entirety of the other surface of the composite body 130 opposing the mounting surface of the composite body 130, whereby the pick-up defects may be significantly decreased at the time of mounting the composite electronic component 100 on the board and substantial effects of product value enhancement through upgrading product quality may be achieved.

The manner of disposing the pigment layer 160 on the other surface of the composite body 130 opposing the mounting surface of the composite body 130 is not particularly limited, but the pigment layer 160 may be disposed by using, for example, a printing process or a process of applying a paste.

In addition, a mark indicating a size of the composite electronic component, a mark indicating a position of the multilayer ceramic capacitor or the inductor configuring the composite electronic component, or the like, may be added onto the pigment layer 160, as necessary.

Meanwhile, the composite electronic component according to the exemplary embodiment of the present inventive concept may include the inductor 120 and the capacitor 110 coupled to each other unlike in a related art. Therefore, the inductor 120 and the capacitor 110 may be designed to have a minimum distance therebetween, whereby an amount of noise may be decreased therein.

In addition, the inductor 120 and the capacitor 110 may be coupled to each other, such that an area of the PMIC on which the inductor 120 and the capacitor 110 are mounted may be significantly decreased, whereby a space in the PMIC may be easily secured for allowing the mounting thereon.

In addition, a cost required for mounting the composite electronic component thereon may be relatively decreased.

Meanwhile, as ever greater degrees of functionality have been provided in electronic apparatuses, amounts of DC-to-DC converters included in the PMIC have been increased. In addition, the amounts of passive components that need to be included in a power input terminal and a power output terminal of the PMIC have also been increased.

In this case, since an area of the electronic apparatuses in which components are disposed is invariably increased, limitations may be placed on the miniaturization of electronic apparatuses.

In addition, a large amount of noise may be generated due to the PMIC and wiring patterns of peripheral circuits of the PMIC.

In order to solve the above-mentioned issues, research into a composite electronic component in which an inductor and a capacitor are coupled to each other in a vertical manner has been conducted, such that effects such as a decrease in an area of the electronic apparatus in which the components are disposed and suppression of noise generation have been obtained.

However, in the case in which the inductor and the capacitor are vertically disposed, as described above, an amount of magnetic flux generated in the inductor has an influence on internal electrodes of the capacitor to generate a parasitic capacitance, and thereby a self resonant frequency (SRF) may move toward a low frequency band.

In the case in which the SRF moves toward the low frequency band, as described above, a frequency range of the inductor that may be used in the exemplary embodiment of the present inventive concept may be relatively narrow.

That is, since a function of the inductor does not operate in a high frequency band of the SRF or above, in the case in which the SRF moves toward the low frequency band, an available frequency range may be limited.

However, according to the exemplary embodiment of the present inventive concept, since the capacitor 110 may be coupled to the side surface of the inductor 120, the amount of influence of the magnetic flux generated in the inductor on the internal electrodes of the capacitor may be significantly decreased to prevent a change in the SRF.

That is, according to the exemplary embodiment of the present inventive concept, the inductor 120 and the capacitor 110 may be designed to have the minimum distance therebetween. Therefore, the amount of noise may be decreased, and the change in the SRF may be prevented, such that a frequency range of the inductor that may be used in a relatively low frequency may not be limited.

Meanwhile, in accordance with the miniaturization of the composite electronic component, a thickness of an internal magnetic layer blocking a magnetic field of the inductor may also be reduced, such that a quality (Q) factor may be deteriorated.

The Q factor refers to a loss of a component or a decrease in efficiency of the component. As a Q value is increased, a loss may be decreased and efficiency may be enhanced.

That is, according to the exemplary embodiment of the present inventive concept, the capacitor 110 may be coupled to the side surface of the inductor 120, such that influences that the respective components may have on each other may be significantly decreased, thereby preventing the deterioration of Q factors of the components.

FIG. 6 is a view illustrating a driving power supplying system supplying driving power to a predetermined terminal requiring the driving power through a battery and a power managing part.

Referring to FIG. 6, the driving power supplying system may include a battery 300, a first power stabilizing part 400, a power managing part 500, and a second power stabilizing part 600.

The battery 300 may supply power to the power managing part 500. As used herein, the power supplied to the power managing part 500 by the battery 300 will be referred to as a first power V1.

The first power stabilizing part 400 may stabilize the first power V1 and may supply the stabilized first power to the power managing part. In detail, the first power stabilizing part 400 may include a capacitor C1 formed between a connection terminal between the battery 300 and the PMIC 500 and a ground. The capacitor C1 may decrease an amount of noise generated in the first power V1.

In addition, the capacitor C1 may be charged with electric charges. In addition, in a case in which the power managing part 500 momentarily consumes a large amount of currents, the capacitor C1 may discharge the electric charges charged therein, thereby suppressing a voltage variation in the power managing part 500.

The capacitor C1 may be a high capacitance capacitor in which the number of stacked dielectric layers is 300 or more.

The power managing part 500 may serve to convert power input to an electronic apparatus into power appropriate for the electronic apparatus, and may distribute, charge, and control the power. Therefore, the power managing part 500 may generally include a direct current (DC)-to-DC converter.

In addition, the power managing part 500 may be provided as a PMIC.

The power managing part 500 may convert the first power V1 into a second power V2. The second power V2 may be required by an active component such as an integrated circuit (IC), or the like, connected to an output terminal of the power managing part 500 to receive driving power from the power managing part 500.

The second power stabilizing part 600 may stabilize the second power V2 and may transfer the stabilized second power to an output terminal Vdd. An active component such as an IC, or the like, receiving the driving power from the power managing part 500 may be connected to the output terminal Vdd.

In detail, the second power stabilizing part 600 may include an inductor L1 connected in series with the power managing part 500 and the output terminal Vdd between the power managing part 500 and the output terminal Vdd. In addition, the second power stabilizing part 600 may include a capacitor C2 formed between a connection terminal between the power managing part 500 and the output terminal Vdd and a ground.

The second power stabilizing part 600 may decrease an amount of noise generated in the second power V2.

In addition, the second power stabilizing part 600 may stably supply the power to the output terminal Vdd.

The inductor L1 may be a power inductor that may be applied to a large amount of currents.

The power inductor may be a high efficiency inductor in which an inductance change is smaller than in a conventional inductor when a DC current is applied thereto. That is, it may be appreciated that the power inductor includes DC bias characteristics, for example, a change in inductance of the power inductor when the DC current is applied thereto in response to the DC current being applied thereto, in addition to a function of the conventional inductor.

In addition, the capacitor C2 may be a high capacitance capacitor.

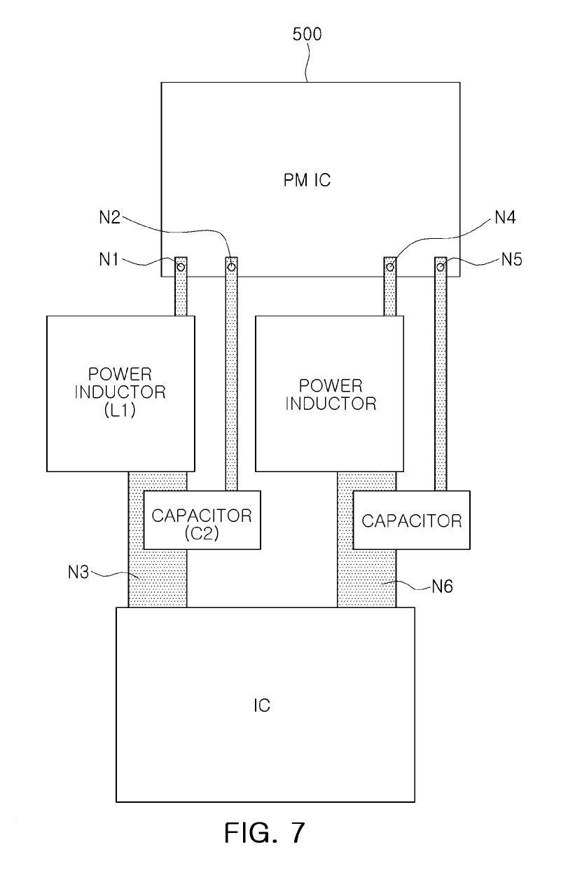

FIG. 7 is a view illustrating a pattern in which the driving power supplying system is disposed.

Referring to FIG. 7, a pattern in which the power managing part 500, the power inductor L1, and the second capacitor C2 are disposed is illustrated.

Generally, the power managing part PMIC 500 may include a few to tens of DC-to-DC converters. In addition, in order to provide a function of the DC-to-DC converter, a power inductor and a high capacitance capacitor may be required in each of the DC-to-DC converters.

Referring to FIG. 7, the power managing part 500 may have predetermined terminals N1 and N2. The power managing part 500 may receive power from the battery and may convert the power using the DC-to-DC converter. In addition, the power managing part 500 may supply the converted power through the first terminal N1. The second terminal N2 may be a ground terminal.

Here, the first power inductor L1 and the second capacitor C2 may receive power from the first terminal N1, may stabilize the power, and may supply driving power through a third terminal N3. Therefore, the first power inductor L1 and the second capacitor C2 may serve as the second power stabilizing part.

Since fourth to sixth terminals N4 to N6 illustrated in FIG. 7 perform the same functions as those of the first to third terminals N1 to N3, a detailed description thereof will be omitted.

In designing a pattern of the driving power supplying system, disposing the power managing part, the power inductor, and the high capacitance capacitor as close to one another as possible may be required. In addition, it may be required to design a wiring of a power line to be relatively short and thick.

In detail, with such requirements being satisfied, an area of a component may be decreased and noise generation may be suppressed.

In a case in which the number of output terminals of the power managing part 500 is small, disposing the power inductor and the high capacitance capacitor close to each other may not be an issue. However, in a case in which several output terminals of the power managing part 500 need to be used, the power inductor and the high capacitance capacitor may not be disposed in a normal manner due to density among the power inductor and the high capacitance capacitor. In addition, an instance in which the power inductor and the high capacitance capacitor need to be disposed in a non-optimal state based on a priority of power may occur.

For example, since sizes of the power inductor and the high capacitance capacitor are great, an instance in which lengths of a power line and a signal line are invariably increased at the time of disposing the actual power inductor and the high capacitance capacitor may occur.

In the case in which the power inductor and the high capacitance capacitor are disposed in the non-optimal state, an interval between the power inductor and the high capacitance capacitor and the power line may be increased, whereby noise may be generated therein. Such noise may have adverse effects on the driving power supplying system.

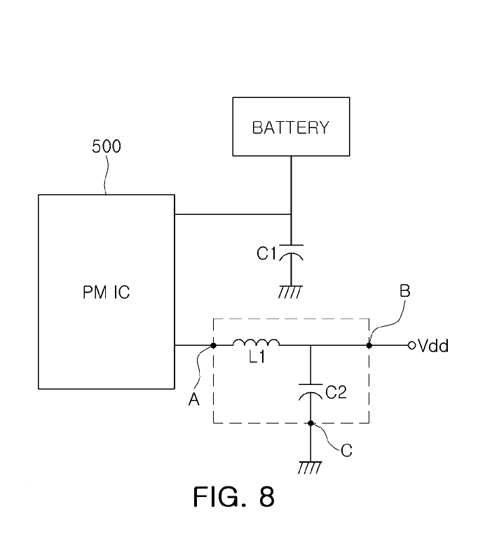

FIG. 8 is a circuit diagram of a composite electronic component according to an exemplary embodiment of the present inventive concept.

Referring to FIG. 8, the composite electronic component may include an input terminal part A, for example, an input terminal, a power stabilizing part, an output terminal part B, for example, an output terminal, and a ground terminal part C, for example, a ground terminal.

The power stabilizing part may include a power inductor L1 and a second capacitor C2.

The composite electronic component 700 may serve as the second power stabilizing part described above.

The input terminal part A may receive power converted by the power managing part 500 to be supplied thereto.

The power stabilizing part may stabilize the power supplied from the input terminal part A.

The output terminal part B may supply the stabilized power to an output terminal Vdd.

The ground terminal part C may connect the power stabilizing part and a ground.

Meanwhile, the power stabilizing part may include the power inductor L1 connected between the input terminal part A and the output terminal part B, and the second capacitor C2 connected between the ground terminal part C and the output terminal part.

Referring to FIG. 8, the power inductor L1 and the second capacitor C2 may share the common output terminal part B, whereby an interval between the power inductor L1 and the second capacitor C2 may be decreased.

As described above, the composite electronic component 700 may be formed by providing the power inductor and the high capacitance capacitor provided in an output power terminal of the power managing part 500 as a single component. Therefore, in the composite electronic component 700, a degree of integration of components may be improved.

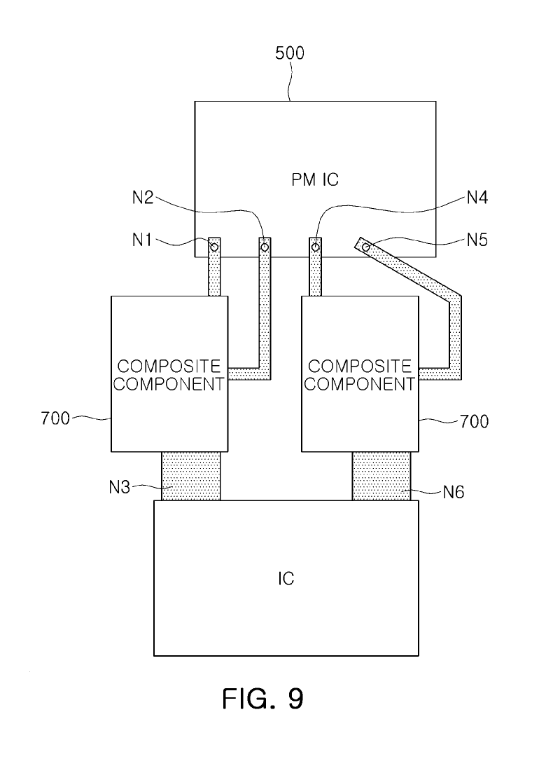

FIG. 9 is a view illustrating a pattern in which a driving power supplying system using a composite electronic component according to an exemplary embodiment of the present inventive concept is disposed.

Referring to FIG. 9, it may be appreciated that the second capacitor C2 and the power inductor L1 illustrated in FIG. 7 have been replaced by a composite electronic component according to an exemplary embodiment of the present inventive concept.

As described above, the composite electronic component may serve as the second power stabilizing part.

In addition, the second capacitor C2 and the power inductor L1 may be replaced by the composite electronic component according to the exemplary embodiment of the present inventive concept, whereby a length of a wiring may be significantly decreased. In addition, the number of components to be disposed may be decreased, whereby the optimal disposition of components may be achieved.

That is, according to the exemplary embodiment of the present inventive concept, the power managing part, the power inductor, and the high capacitance capacitor may be disposed as closely to each other as possible, and the wiring of the power line may be designed to be short and thick to thereby decrease an amount of noise therein.

Meanwhile, electronic apparatus manufacturers have attempted to decrease a size of a printed circuit board (PCB) included in an electronic apparatus in order to satisfy demands from consumers. Therefore, there have been needs to increase a degree of integration of ICs to be mounted on the PCB. By providing a plurality of components as a single composite component as in the case of the composite electronic component according to the exemplary embodiment of the present inventive concept, such requirements may be satisfied.

Further, according to the exemplary embodiment of the present inventive concept, two components, the second capacitor and the power inductor, may be provided as a single composite electronic component, whereby an area of the PCB on which the second capacitor and the power inductor are mounted may be decreased. According to the present exemplary embodiment, an area of the PCB on which the components are mounted may be decreased as compared to a case of an existing disposition pattern by about 30 to 60%.

Further, according to the exemplary embodiment of the present inventive concept, the power managing part 500 may supply power to the IC receiving driving power using a wiring having a minimum length.

In addition, in the composite electronic component according to the exemplary embodiment of the present inventive concept, since the capacitor is disposed on the side surface of the inductor, the amount of influence of the magnetic flux generated in the inductor on the internal electrodes of the capacitor may be significantly decreased to prevent the change in the SRF.

In addition, in the composite electronic component according to the exemplary embodiment of the present inventive concept, the capacitor may be disposed on the side surface of the inductor to prevent the Q factor of the component from being deteriorated.

Board Having Multilayer Ceramic Capacitor

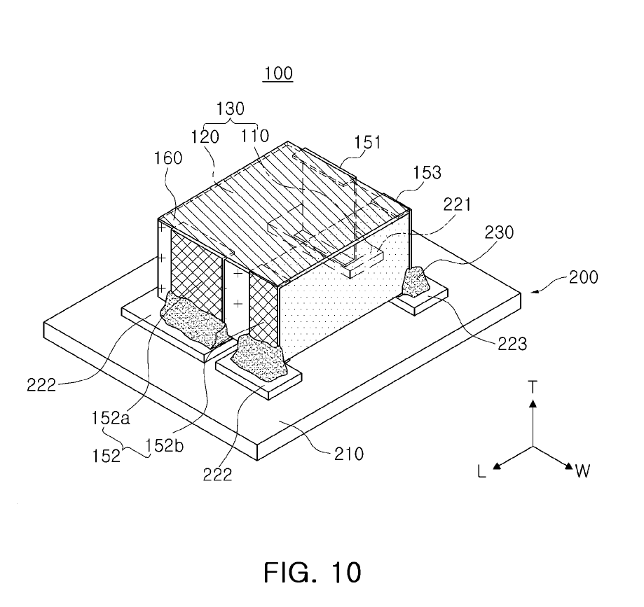

FIG. 10 is a perspective view illustrating a form in which the composite electronic component of FIG. 1 is mounted on a PCB.

Referring to FIG. 10, a board 200 having a composite electronic component 100 according to an exemplary embodiment of the present inventive concept may include a PCB 210 on which the composite electronic component 100 is mounted and three or more electrode pads 221 to 223 formed on an upper surface of the PCB 210.

The electrode pads may be first to third electrode pads 221 to 223 connected to the input terminal 151, the output terminal 152, and the ground terminal 153 of the composite electronic component, respectively.

Here, the input terminal 151, the output terminal 152, and the ground terminal 153 of the composite electronic component 100 may be electrically connected to the PCB 210 by solders 230 in a state in which the input terminal 151, the output terminal 152, and the ground terminal 153 are positioned on the first to third electrode pads 221 to 223, respectively, so as to be in contact with the first to third electrode pads 221 to 223, respectively.

In addition, since the component electronic component mounted on the PCB may be a composite electronic component according to another exemplary embodiment of the present inventive concept, a description of the composite electronic component according to the other exemplary embodiment of the present inventive concept will be omitted in order to avoid a repeated description.

Packaging Unit of Composite Electronic Component

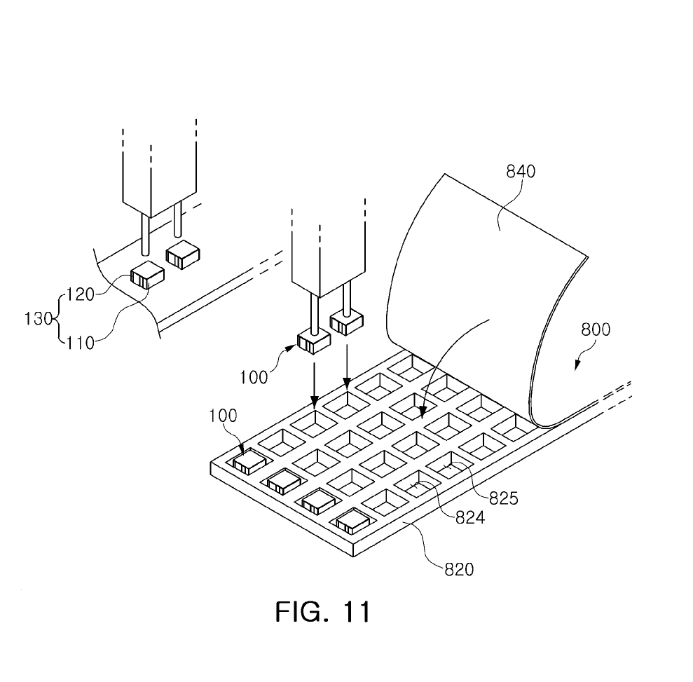

FIG. 11 is a schematic perspective view illustrating a form in which the composite electronic components of FIG. 1 are mounted on a packaging unit.

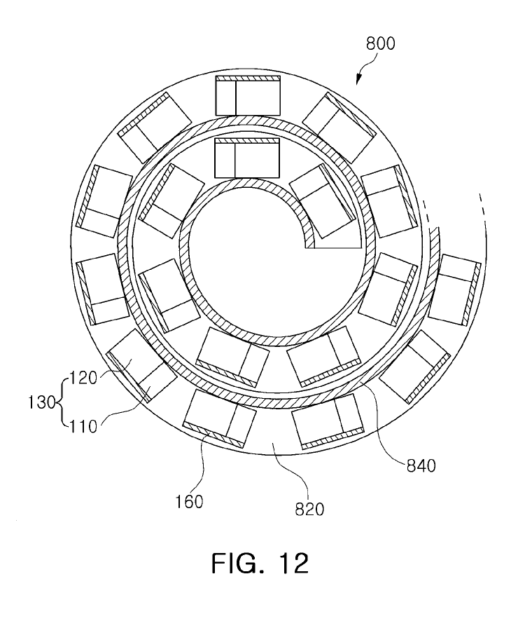

FIG. 12 is a schematic cross-sectional view illustrating the packaging unit of FIG. 11 wound in a coil form.

Referring to FIG. 11, a packaging unit 800 of a composite electronic component according to the present exemplary embodiment may include a packaging sheet 820 having accommodating parts 824 formed therein, the accommodating parts 824 accommodating the composite electronic components 100 therein, respectively.

The accommodating parts 824 of the packaging sheet 820 may have shapes corresponding to those of the composite electronic components 100, and the pigment layers 160 may be disposed to face upward, based on bottom surfaces 825 of the accommodating parts 824, respectively.

The composite electronic components 100 may be maintained in a state of being aligned with one another so that the pigment layers 160 face upward, by using an electronic component aligning apparatus and may be transferred to the packaging sheet 820 by using a transferring apparatus.

Therefore, the composite electronic components 100 accommodated in the accommodating parts 824, respectively, may be disposed so that the pigment layers 160 face upward, based on the bottom surfaces of the respective accommodating parts 824.

Through the above-mentioned manner, the plurality of composite electronic components 100 in the packing sheet 820 may be disposed to have the same directionality therein.

The packaging unit 800 of the composite electronic component may further include a packaging film 840 covering the packaging sheet 820 in which the component electronic components 100 disposed so that the pigment layers 160 face upward, based on the bottom surfaces of the respective accommodating parts 824 are accommodated.

Referring to FIG. 12, the packaging unit 800 of the composite electronic component wound in the coil form is illustrated, and may be formed by continuous winding of the coil.

As set forth above, according to exemplary embodiments of the present inventive concept, the step difference that may be generated on a coupling surface between a plurality of components may be reduced, and thus the pick-up defects at the time of mounting the composite electronic component on the board may be prevented.

In addition, according to exemplary embodiments of the present inventive concept, the composite electronic component able to be mounted in a relatively decreased area of the driving power supplying system may be provided.

Further, according to exemplary embodiments of the present inventive concept, the composite electronic component capable of suppressing noise generation in the driving power supplying system may be provided.

Further, in the composite electronic component according to an exemplary embodiment of the present inventive concept, since the capacitor is disposed on the side surface of the inductor, an influence of the magnetic flux generated in the inductor on the internal electrodes of the capacitor may be significantly decreased to prevent the change in the SRF.

Further, in the composite electronic component according to the exemplary embodiment of the present inventive concept, the capacitor may be disposed on the side surface of the inductor to prevent the Q factor of the component from being deteriorated.

While exemplary embodiments have been shown and described above, it will be apparent to those skilled in the art that modifications and variations could be made without departing from the scope of the present invention as defined by the appended claims.

What is claimed is:

1. A composite electronic component comprising:
a composite body having a capacitor and an inductor coupled to each other, the capacitor including a ceramic body in which a plurality of dielectric layers and first and second internal electrodes disposed to oppose each other with each of the dielectric layers interposed therebetween are stacked, and the inductor including a magnetic body including a coil part;
an input terminal disposed on a first side surface of the composite body in a length direction of the composite body and connected to the coil part of the inductor;
an output terminal including a first output terminal disposed on a second side surface of the composite body in the length direction of the composite body and connected to the coil part of the inductor and a second output terminal disposed on the second side surface of the composite body in the length direction of the composite body and connected to the first internal electrode of the capacitor; and
a ground terminal disposed on the first side surface of the composite body in the length direction of the composite body and connected to the second internal electrode of the capacitor,
wherein the composite body has a pigment layer disposed on the other surface of the composite body opposing a mounting surface of the composite body.

2. The composite electronic component of claim 1, wherein the magnetic body has a form in which a plurality of magnetic layers having conductive patterns respectively formed thereon are stacked, the conductive pattern forming the coil part.

3. The composite electronic component of claim 1, wherein the inductor has a thin film form in which the magnetic body includes an insulating substrate and a coil formed on at least one surface of the insulating substrate.

4. The composite electronic component of claim 1, wherein the magnetic body has a form in which the magnetic body includes a core and a winding coil wound around the core.

5. The composite electronic component of claim 1, wherein the inductor is a power inductor.

6. The composite electronic component of claim 1, wherein the capacitor and the inductor are connected to each other by a conductive adhesive.

7. The composite electronic component of claim 1, wherein the capacitor is coupled to a side surface of the inductor.

8. The composite electronic component of claim 1, wherein the pigment layer contains one or more of an epoxy resin, an organic pigment, and an inorganic pigment.

9. The composite electronic component of claim 1, wherein the pigment layer is disposed on the entirety of the other surface of the composite body opposing the mounting surface of the composite body.

10. The composite electronic component of claim 1, wherein a mark indicating a size of the composite electronic component or a mark indicating a position of the capacitor or the inductor is further provided on the pigment layer.

11. A composite electronic component comprising:
an input terminal receiving power converted by a power managing part to be supplied thereto;
a power stabilizing part stabilizing the power and including a composite body having a capacitor and an inductor coupled to each other, the capacitor including a ceramic body in which a plurality of dielectric layers and first and second internal electrodes disposed to oppose each other with each of the dielectric layers interposed therebetween are stacked and being coupled to a side surface of the inductor, and the inductor including a magnetic body including a coil part;
an output terminal supplying the stabilized power; and
a ground terminal for a connection to a ground,
wherein the composite body has a pigment layer disposed on the other surface of the composite body opposing a mounting surface of the composite body.

12. The composite electronic component of claim 11, wherein the input terminal is disposed on a first side surface of the composite body in a length direction of the composite body,
the output terminal includes a first output terminal disposed on a second side surface of the composite body in the length direction of the composite body and connected to the coil part of the inductor and a second output terminal disposed on the second side surface of the composite body in the length direction of the composite body and connected to the first internal electrode of the capacitor, and
the ground terminal is disposed on the first side surface of the composite body in the length direction of the composite body and is connected to the second internal electrode of the capacitor.

13. The composite electronic component of claim 11, wherein the magnetic body has a form in which a plurality of magnetic layers having conductive patterns respectively formed thereon are stacked, the conductive patterns forming the coil part.

14. The composite electronic component of claim 11, wherein the inductor has a thin film form in which the magnetic body includes an insulating substrate and a coil formed on at least one surface of the insulating substrate.

15. The composite electronic component of claim 11, wherein the magnetic body has a form in which the magnetic body includes a core and a winding coil wound around the core.

16. The composite electronic component of claim 11, wherein the inductor is a power inductor.

17. The composite electronic component of claim 11, wherein the pigment layer contains one or more of an epoxy resin, an organic pigment, and an inorganic pigment.

18. The composite electronic component of claim 11, wherein the pigment layer is disposed on the entirety of the other surface of the composite body opposing the mounting surface of the composite body.

19. The composite electronic component of claim 11, wherein a mark indicating a size of the composite electronic component or a mark indicating a position of the capacitor or the inductor is further provided on the pigment layer.

20. A board having a composite electronic component, comprising:
a printed circuit board (PCB) having three or more electrode pads disposed thereon;
the composite electronic component of claim 1 mounted on the PCB; and
solders respectively connecting the electrode pads to the composite electronic component.

21. A packaging unit of a composite electronic component, comprising:
the composite electronic component of claim 1; and
a packaging sheet having an accommodating part formed therein, the accommodating part accommodating the composite electronic component therein,
wherein the pigment layer is disposed to face upward, based on a bottom surface of the accommodating part.

22. The packaging unit of claim 21, further comprising a packaging film coupled to the packaging sheet and covering the component electronic component.

23. The packaging unit of claim 21, wherein the packaging sheet in which the composite electronic component is accommodated is wound in a coil form.
